(19) United States
(12) Patent Application Publication
(10) Pub. No.: US 2026/0198099 A1
(43) Pub. Date: Jul. 9, 2026

(54) DIODE/CLAMP FOR ESD PROTECTION AND FRONTSIDE CONDUCTIVE LAYER RESISTOR FOR THERMAL SENSING

(71) Applicant: Taiwan Semiconductor Manufacturing Company, Ltd., Hsinchu (TW)

(72) Inventors: Hsin-Yuan Yu, Hsinchu (TW); Wei-Lin Lai, Hsinchu (TW); Tao-Yi Hung, Hsinchu (TW); Wun-Jie Lin, Hsinchu (TW)

(21) Appl. No.: 19/013,198

(22) Filed: Jan. 8, 2025

(51) Int. Cl. H10D 89/60; H01L 23/48; H10D 8/50; H10D 84/00

(52) U.S. Cl. CPC H10D 89/611; H10D 8/50; H10D 84/204; H10W 20/20

(57) ABSTRACT

A device includes a substrate and a first PIN diode for ESD protection situated in the substrate. The first PIN diode has a first region, a second region, and a first intrinsic semiconductor region situated between the first region and the second region. The device further includes a first backside via connected to the first region and to a backside pad contact, a second backside via connected to the second region and to a first backside power contact, and a first frontside conductive layer resistor for thermal sensing having a first end connected to the first region and a second end connected to the second region, where at least a portion of the first frontside conductive layer resistor is situated within a first footprint of the first PIN diode.

### BACKGROUND

Typically, an integrated circuit (IC) includes electro-static discharge (ESD) protection circuits to prevent damage from ESD events that can cause permanent IC damage or degrade IC performance. ESD protection techniques include ESD protection diodes, ESD protection networks formed by combining multiple ESD protection diodes into a specific configuration, grounding and shielding, ESD protection cells that provide localized ESD protection to components and/or areas within the IC, and system-level ESD protection, such as external ESD protection devices at the input/output (IO) pins of the IC.

Also, often an IC includes a thermal sensor to measure a temperature of the IC or its surroundings. Typically, an IC thermal sensor includes a temperature-sensing element and associated circuitry to measure and convert the temperature into a readable format. The temperature-sensing element may be based on elements, such as PN junction diodes, resistors, thermocouples, bandgap voltage references, and current-based sensors. The thermal sensor provides temperature feedback for controlling cooling mechanisms like fans or heatsinks, optimizing performance of the IC by adjusting operational parameters, and ensuring protection of the IC by triggering warnings or shutdown mechanisms if the temperature exceeds safe limits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating an IC that includes devices that integrate the functions of ESD protection and thermal sensing, in accordance with some embodiments.

FIG. 2 is a diagram schematically illustrating an ESD protection and thermal sensing device, in accordance with some embodiments.

FIG. 3 is a diagram schematically illustrating a cross-section of an ESD protection and thermal sensing device, in accordance with some embodiments.

FIG. 4 is a diagram schematically illustrating a semiconductor layout of an ESD protection and thermal sensing device, in accordance with some embodiments.

FIG. 5 is a diagram schematically illustrating a plan layout of an ESD protection and thermal sensing device, in accordance with some embodiments.

FIG. 6 is a diagram schematically illustrating an ESD protection and thermal sensing device that includes a power clamp, in accordance with some embodiments.

FIG. 7 is a diagram schematically illustrating a table for verifying the status of the BEOL resistors and the PIN diodes in the ESD protection and thermal sensing devices, in accordance with some embodiments.

FIG. 8 is a diagram schematically illustrating a power clamp device that is an ESD protection and thermal sensing device, in accordance with some embodiments.

FIG. 9 is a diagram schematically illustrating an active trigger circuit, in accordance with some embodiments.

FIG. 10 is a diagram schematically illustrating a bigFET, in accordance with some embodiments.

FIG. 11 is a diagram schematically illustrating an ESD protection and thermal sensing device, in accordance with some embodiments.

FIG. 12 is a diagram schematically illustrating a method of manufacturing an ESD protection and thermal sensing device, in accordance with some embodiments.

FIG. 13 is a block diagram schematically illustrating an example of a computer system configured to provide the devices, including electronic devices and semiconductor devices, and methods of the current disclosure, in accordance with some embodiments.

FIG. 14 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In an IC, a thermal sensor can be protected from ESD events by an ESD protection circuit. For example, thermal sensor resistors may have one end connected to an IO pad and another end connected to a VDD power contact or a VSS power contact. These thermal sensor resistors are not self-protected from ESD events. Instead, an ESD protection circuit is connected between the VDD power contact and the VSS power contact to protect the thermal sensor resistors from ESD events. The thermal sensor resistors are situated off to one or more sides of the ESD protection circuit, which creates a large footprint for the thermal sensor resistors and the ESD protection circuit. The large footprint takes up a large area on the IC. In addition, when measuring resistance of the thermal sensor resistors, the thermal sensitivity of the ESD protection circuit can affect the resistance measurement, which leads to reduced accuracy of the thermal sensor.

Disclosed embodiments provide a device that includes an integrated layout of an ESD protection circuit and a thermal sensor. In some embodiments, the ESD protection circuit includes a PIN diode matrix in a substrate and at least one PIN diode in the PIN diode matrix for ESD protection. Each of the PIN diodes includes a first doped region, a second doped region, and an intrinsic semiconductor region situated between the first doped region and the second doped region. The thermal sensor includes at least one back-end-of-line (BEOL) resistor. The BEOL resistor includes frontside conductive layer lines connected to form a resistor. In some embodiments, the BEOL resistor is made of only frontside conductive layer lines and vias or structures that connect them together. In some embodiments, the frontside conductive layer lines that make up the BEOL resistor are frontside metal layer lines.

At least a portion of the at least one BEOL resistor is situated within a footprint of the at least one PIN diode, such that the footprint of the at least one PIN diode including the BEOL resistor is smaller than the larger footprint of the thermal sensor and ESD protection circuit having thermal sensor resistors situated off to one or more sides of the ESD protection circuit. In some embodiments, the at least one BEOL resistor is part of the PIN diode matrix, such that the footprint of the PIN diode matrix including the BEOL resistor is smaller than the large footprint of the thermal sensor and the ESD protection circuit having thermal sensor resistors situated off to one or more sides of the ESD protection circuit. The smaller footprint of the at least one PIN diode or the PIN diode matrix that includes at least a portion of the BEOL resistor provides both a thermal sensor resistor and an ESD protection circuit. In some embodiments, the smaller footprint of the at least one PIN diode or the PIN diode matrix including the BEOL resistor is a minimum sized footprint.

In some embodiments, a stress pin and a sense pin are connected to the at least one BEOL resistor for sensing resistance and temperature of the at least one BEOL resistor. In this situation, the thermal sensitivity of the ESD protection circuit does not affect the resistance and temperature measurement, such that the thermal sensor is more accurate. In some embodiments, the stress pin and the sense pin are frontside conductive layer lines connected to a controller for determining the resistance of the BEOL resistor(s) and the temperature of the device.

Disclosed embodiments further include an ESD power clamp device that includes a power clamp voltage divider including a first BEOL resistor having a first end connected to a VDD power contact and a second end connected to a voltage divider node, and a second BEOL resistor having a third end connected to the voltage divider node and a fourth end connected to a VSS power contact. The ESD power clamp device further includes an ESD detection circuit, an active trigger circuit, and a field effect transistor (FET) circuit connected on a first side to the VDD power contact and on a second side to the VSS power contact for ESD protection. The ESD power clamp device includes the power clamp voltage divider as a thermal sensor having one of a sense or stress pin at the VDD power contact and another one of the sense or stress pin at the VSS power contact, and it includes an ESD power clamp for ESD protection.

Further disclosed embodiments include integrating an ESD protection circuit into an analog thermal front end (TFE) of a thermal sensor to improve power, performance, and area for thermal sensing and ESD protection circuit. The device includes an analog TFE that includes a BEOL resistor and a high resistance reference resistor for determining resistance and temperature of the IC and either an embedded power clamp or a diode clamp, such as a PIN diode clamp, for ESD protection.

Still further disclosed embodiments, include a method of manufacturing a device. The method includes forming a PIN diode matrix in a substrate, forming a BEOL resistor having a first end connected to a first doped region of a PIN diode and a second end connected to a second doped region of the PIN diode, where the PIN diode matrix includes the PIN diode and the BEOL resistor, such that at least a portion of the BEOL resistor is situated within a footprint of the PIN diode matrix, forming a first backside via connected to the first doped region and to a backside pad contact, and forming a second backside via connected to the second doped region and to a backside power contact.

Advantages of the disclosed embodiments include integrating thermal sensing and ESD protection in the IC, reducing a footprint of the device, and increasing the accuracy of the resistance and temperature measurements by using BEOL resistors. Also, BEOL resistors embedded in PIN diodes and BEOL resistors integrated into power clamps are compatible with frontside/backside routing. In addition, BEOL resistors embedded in PIN diodes and BEOL resistors integrated into power clamps are compatible with frontside-only routing.

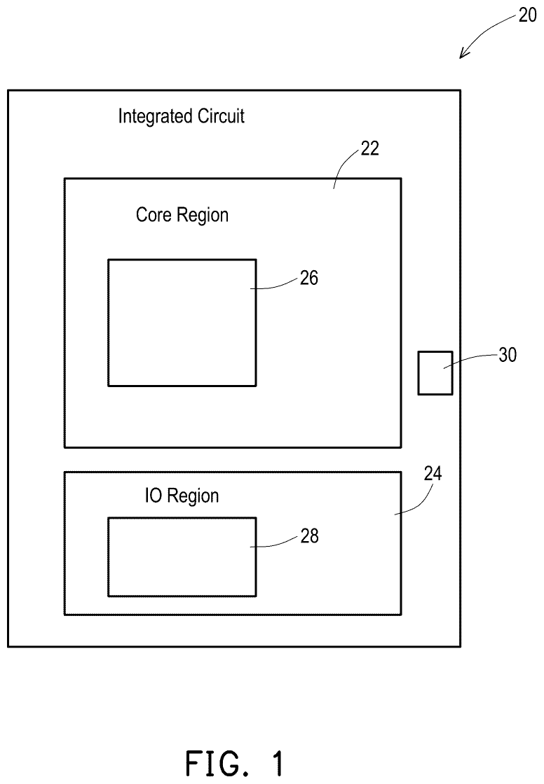

FIG. 1 is a diagram schematically illustrating an IC 20 that includes devices that integrate the functions of ESD protection and thermal sensing, in accordance with some embodiments. The IC 20 can be an electronic device, one or more semiconductor devices, and/or one or more IC devices.

The IC 20 includes a core region 22 and an IO region 24. The core region 22 includes circuits, such as digital and/or analog circuits, for performing functions of the IC 20. The IO region 24 includes circuits, such as IO circuits, for receiving and transmitting data to and from the IC 20. The core region 22 includes a first device 26 configured to provide ESD protection for the core region 22 and a thermal sensor for sensing the temperature of the IC 20. The IO region 24 includes a second device 28 configured to provide ESD protection for the IO region 24 and for sensing the temperature of the IC 20. In some embodiments, the IC 20 includes an internal circuit, such as control circuit 30, for determining the temperature of the IC 20 via the first device 26 and/or the second device 28, such as by measuring a resistance in the first device 26 and/or a resistance in the second device 28 and determining the temperature of the IC 20 based on the measured resistance(s).

In some embodiments, the IC 20 includes only one or more devices like the first device 26 for providing ESD protection for the core region 22 and a thermal sensor for sensing the temperature of the IC 20. In some embodiments, the IC 20 includes only one or more devices like the second device 28 for providing ESD protection for the IO region 24 and for sensing the temperature of the IC 20. In some embodiments, the IC 20 includes one or more devices like the first device 26 for providing ESD protection for the core region 22 and a thermal sensor for sensing the temperature of the IC 20 and one or more devices like the second device 28 for providing ESD protection for the IO region 24 and for sensing the temperature of the IC 20.

Each of the first device 26 and the second device 28 integrates the functions of ESD protection and thermal sensing into one device that is configured to provide the ESD protection and thermal sensing functions independently. This results in reducing the footprint of the device and increasing the accuracy of the resistance and temperature measurements.

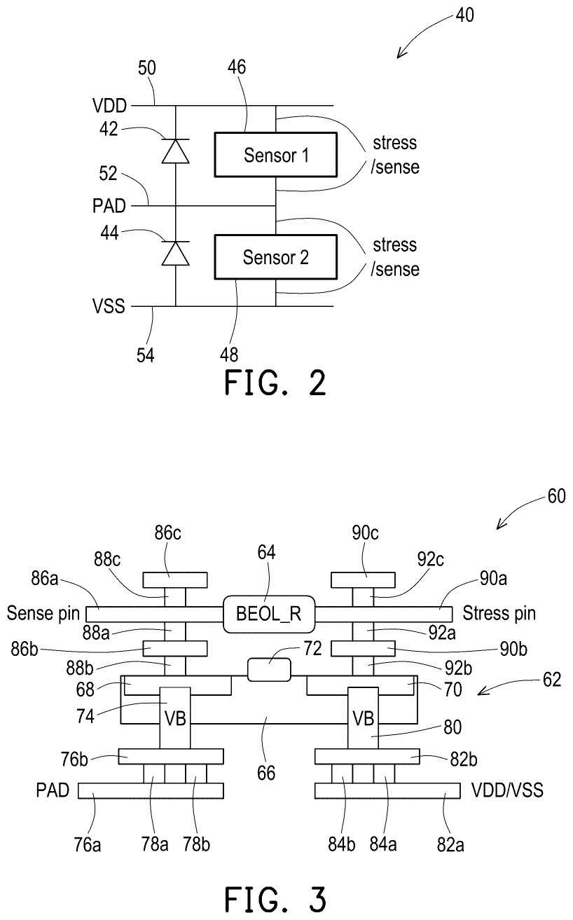

FIG. 2 is a diagram schematically illustrating an ESD protection and thermal sensing device 40, in accordance with some embodiments. The device 40 includes a first PIN diode 42, a second PIN diode 44, a first sensor 46, and a second sensor 48. In some embodiments, the device 40 is part of an IC, such as the IC 20 of FIG. 1. In some embodiments, the device 40 is like the first device 26 (shown in FIG. 1). In some embodiments, the device 40 is like the second device 28 (shown in FIG. 1).

The first PIN diode 42 includes a cathode connected to a VDD power contact 50 and an anode connected to a PAD contact 52. The first PIN diode 42 shunts ESD events from the PAD contact 52 to the VDD power contact 50 and from the VDD power contact 50 to the PAD contact 52. In some embodiments, the cathode of the first PIN diode 42 is an N+ region. In some embodiments, the anode of the first PIN diode 42 is a P+ region.

The second PIN diode 44 includes a cathode connected to the PAD contact 52 and an anode connected to a VSS power contact 54. The second PIN diode 44 shunts ESD events from the PAD contact 52 to the VSS power contact 54 and from the VSS power contact 54 to the PAD contact 52. In some embodiments, the cathode of the second PIN diode 44 is an N+ region. In some embodiments, the anode of the second PIN diode 44 is a P+ region.

The first sensor 46 has one end connected to the VDD power contact 50 and another end connected to the PAD contact 52. One end of the first sensor 46 is connected to one of a stress pin or a sense pin and the other end of the first sensor 46 is connected to the other one of the stress pin or the sense pin. A voltage and/or current is applied to the stress pin of the first sensor 46 and a measurement is obtained at the sense pin of the first sensor 46 to determine the temperature of the device 40. For example, if the first sensor 46 is a resistor, a voltage and/or current is applied at the stress pin and a measurement of the resistance of the resistor is obtained at the sense pin. From this resistance measurement, a control circuit, such as control circuit 30 in the IC 20, determines the temperature of the device 40. In some embodiments, the first sensor 46 includes a resistor. In some embodiments, the first sensor 46 includes a BEOL resistor.

The second sensor 48 has one end connected to the PAD contact 52 and another end connected to the VSS power contact 54. One end of the second sensor 48 is connected to one of a stress pin or a sense pin and the other end of the second sensor 48 is connected to the other one of the stress pin or the sense pin. A voltage and/or current is applied to the stress pin of the second sensor 48 and a measurement is obtained at the sense pin of the second sensor 48 to determine the temperature of the device 40. For example, if the second sensor 48 is a resistor, a voltage and/or current is applied at the stress pin and a measurement of the resistance of the resistor is obtained at the sense pin. From this resistance measurement, a control circuit, such as control circuit 30 in the IC 20, determines the temperature of the device 40. In some embodiments, the second sensor 48 includes a resistor. In some embodiments, the second sensor 48 includes a BEOL resistor. Also, in some embodiments, the resistance values of the first sensor 46 and the second sensor 48 are combined to determine the temperature of the device 40 or IC that the device 40 is part of.

The device 40 integrates the functions of ESD protection and thermal sensing into one device 40 that is configured to provide the ESD protection and thermal sensing functions independently. This results in increasing the accuracy of the resistance and temperature measurements.

FIG. 3 is a diagram schematically illustrating a cross-section of an ESD protection and thermal sensing device 60, in accordance with some embodiments. The device 60 includes a PIN diode 62 and a BEOL resistor 64 that is connected to the PIN diode 62 through frontside conductive layer lines or tracks. The BEOL resistor 64 is a thermal sensing device or thermal sensor. The BEOL resistor 64 includes frontside conductive layer lines connected to form the BEOL resistor 64. In some embodiments, the BEOL resistor 64 is made of only frontside conductive layer lines and vias or structures that connect them together. In some embodiments, the frontside conductive layer lines that make up the BEOL resistor 64 are frontside metal layer lines. In some embodiments, the PIN diode 62 and the BEOL resistor 64 are like the first PIN diode 42 and the first sensor 46 (shown in FIG. 2). In some embodiments, the PIN diode 62 and the BEOL resistor 64 are like the second PIN diode 44 and the second sensor 48 (shown in FIG. 2).

The device 60 includes the PIN diode 62 in a substrate 66. The PIN diode 62 provides ESD protection and includes a first doped region 68, a second doped region 70, and an intrinsic semiconductor region 72 situated between the first doped region 68 and the second doped region 70. A first backside via (VB) 74 is connected to the first doped region 68 and to a backside pad contact 76a through a first backside conductive layer track 76b and first backside vias 78a and 78b. A second backside via (VB) 80 is connected to the second doped region 70 and to a VDD/VSS backside power contact 82a, which is either a VDD backside power contact 82a or a VSS backside power contact 82a, through a second backside conductive layer track 82b and second backside vias 84a and 84b. The PIN diode 62 provides ESD protection through the backside bump outs or backside contacts including the backside pad contact 76a and the VDD/VSS backside power contacts 82a. With the first backside via (VB) 74 connected to the first doped region 68 and to the backside pad contact 76a and the second backside via (VB) 80 connected to the second doped region 70 and to the VDD/VSS backside power contacts 82a, the device 60 provides improved ESD protection through the backside vias (VBs) as compared to through feed-through-vias (FTVs). In some embodiments, the first doped region 68 is a P+ region connected to the backside pad contact 76a and the second doped region 70 is an N+ region connected to the VDD backside power contact 82a. In some embodiments, the first doped region 68 is an N+ region connected to the backside pad contact 76a and the second region is a P+ region connected to the VSS backside power contact 82a.

The BEOL resistor 64 is for thermal sensing and has a first end connected to the first doped region 68 through first frontside conductive layer tracks 86a and 86b and first frontside vias 88a and 88b, and a second end connected to the second doped region 70 through second frontside conductive layer tracks 90a and 90b and second frontside vias 92a and 92b. Also, a first frontside conductive layer track 86c is connected to the first frontside conductive layer track 86a through a first frontside via 88c, and a first frontside conductive layer track 90c is connected to the first frontside conductive layer track 90a through a first frontside via 92c, which improves ESD protection performance by providing a smaller on resistance (Ron).

The BEOL resistor 64 is situated above the PIN diode 62, such that at least a portion of the BEOL resistor 64 is situated within a footprint of the PIN diode 62. In some embodiments, the first frontside conductive layer track 86a is a sense pin connected to the first end of the BEOL resistor 64 and the second frontside conductive layer contact 90a is a stress pin connected to the second end of the BEOL resistor 64, where the BEOL resistor 64 is stressed, i.e., has a voltage and/or current applied, and sensed, i.e., has the resistance measured, through the stress pin and the sense pin, respectively. In some embodiments, the first frontside conductive layer track 86a is a sense pin and the second frontside conductive layer contact 90a is a stress pin, which are connected to an internal circuit of the IC that the device 60 is part of, such as control circuit 30 in the IC 20, for measuring the resistance of the BEOL resistor 64 and the temperature of the IC. In some embodiments, the BEOL resistor 64 is stressed and sensed through the backside power contact 82a and the backside pad contact 76a, respectively. In some embodiments, the backside power contact 82a and the backside pad contact 76a are connected to an external circuit for measuring the resistance of the BEOL resistor 64 and the temperature of the IC.

The device 60 integrates the functions of ESD protection and thermal sensing into one compact device. The device 60 provides ESD protection through backside contacts and thermal sensing through frontside stress and sense pin contacts, independently, which increases the accuracy of the resistance and temperature measurements. Also, the BEOL resistor 64 is situated above the PIN diode 62, such that at least a portion of the BEOL resistor 64 is situated within a footprint of the PIN diode 62, which reduces the footprint, i.e., the area on the IC, of the device 60.

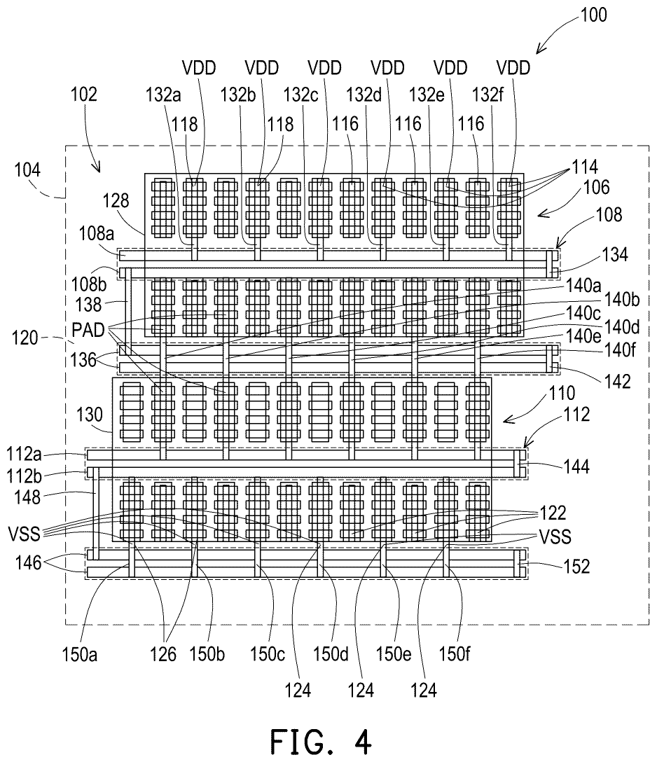

FIG. 4 is a diagram schematically illustrating a semiconductor layout of an ESD protection and thermal sensing device 100, in accordance with some embodiments. The device 100 includes a PIN diode matrix 102 that includes multiple PIN diodes situated in a substrate, such as the substrate 66 (shown in FIG. 3). The PIN diode matrix 102 has a PIN diode matrix footprint 104.

The device 100 includes a first PIN diode 106 and a first BEOL resistor 108 that is connected to the first PIN diode 106 through frontside conductive layer tracks. Also, the device 100 includes a second PIN diode 110 and a second BEOL resistor 112 that is connected to the second PIN diode 110 through frontside conductive layer tracks. The first PIN diode 106 and the second PIN diode 110 provide ESD protection for the IC including the first BEOL resistor 108 and the second BEOL resistor 112. Each of the first BEOL resistor 108 and the second BEOL resistor 112 is a thermal sensing device or thermal sensor. In some embodiments, the first PIN diode 106 and the first BEOL resistor 108 are like the first PIN diode 42 and the first sensor 46 (shown in FIG. 2). In some embodiments, the second PIN diode 110 and the second BEOL resistor 112 are like the second PIN diode 44 and the second sensor 48 (shown in FIG. 2). In some embodiments, the frontside conductive layer tracks are lower conductive metal tracks, such as metal 3 conductive layer tracks. In some embodiments, each of the first BEOL resistor 108 and the second BEOL resistor 112 is made from conductive layer tracks, such as metal 4 conductive layer tracks.

The device 100 includes the PIN diode matrix 102 that includes the first PIN diode 106 and the second PIN diode 110. The first PIN diode 106 includes multiple first doped regions 114, such as N+ regions, multiple second doped regions 116, such as P+ regions, and multiple intrinsic semiconductor regions (not shown for clarity) situated between the first doped regions 114 and the second doped regions 116. The multiple first doped regions 114 are electrically connected to each other and electrically connected to a VDD backside power contact 118 through backside vias (VBs) and backside conductive layer tracks. The multiple second doped regions 116 are electrically connected to each other and electrically connected to a backside PAD contact 120 through backside vias (VBs) and backside conductive layer tracks. The first PIN diode 106 provides ESD protection through the backside bump outs or backside contacts including the backside pad contact 120 and the VDD backside power contact 118. The first PIN diode 106 provides improved ESD protection through the backside vias (VBs) as compared to through feed-through-vias (FTVs).

The second PIN diode 110 includes multiple first doped regions 122, such as N+ regions, multiple second doped regions 124, such as P+ regions, and multiple intrinsic semiconductor regions (not shown for clarity) situated between the first doped regions 122 and the second doped regions 124. The multiple first doped regions 122 are electrically connected to each other and electrically connected to the backside PAD contact 120 through backside vias (VBs) and backside conductive layer tracks. The multiple second doped regions 124 are electrically connected to each other and electrically connected to a VSS backside power contact 126 through backside vias (VBs) and backside conductive layer tracks. The second PIN diode 110 provides ESD protection through the backside bump outs or backside contacts including the backside pad contact 120 and the VSS backside power contact 126. The second PIN diode 110 provides improved ESD protection through the backside vias (VBs) as compared to through feed-through-vias (FTVs).

The device 100 includes the first BEOL resistor 108 connected to the first PIN diode 106 through frontside conductive layer tracks. The first BEOL resistor 108 is situated in the first PIN diode 106, such that at least a portion of the first BEOL resistor 108 is situated within a footprint 128 of the first PIN diode 106. Also, the device 100 includes the second BEOL resistor 112 connected to the second PIN diode 110 through frontside conductive layer tracks. The second BEOL resistor 112 is situated in the second PIN diode 110, such that at least a portion of the second BEOL resistor 112 is situated within a footprint 130 of the second PIN diode 110. In addition, each of the first BEOL resistor 108 and the second BEOL resistor 112 is situated in the PIN diode matrix footprint 104.

The first BEOL resistor 108 is for thermal sensing and has a first end portion 108a connected to the multiple first doped regions 114 of the first PIN diode 106 through frontside conductive layer tracks 132a-132f. The multiple first doped regions 114 are electrically connected to each other and electrically connected to the VDD backside power contact 118 through backside vias (VBs) and backside conductive layer tracks. The first BEOL resistor 108 includes the first end portion 108a connected to a second portion 108b through a frontside conductive layer track 134, which is connected to a PAD node 136 through a frontside conductive layer track 138. The PAD node 136 includes two frontside conductive layer tracks connected to each other through frontside conductive layer tracks 140a-140f and 142 and to the second doped regions 116 through the frontside conductive layer tracks 140a-140f. In some embodiments, the frontside conductive layer tracks 132a-132f, 134, 138, 140a-140f, and 142 are lower frontside conductive metal tracks, such as metal 3 conductive layer tracks. In some embodiments, the first BEOL resistor 108 including 108a and 108b, and the PAD node 136 are made from frontside conductive layer tracks, such as metal 4 conductive layer tracks.

The second BEOL resistor 112 is for thermal sensing and has a first end portion 112a connected to the multiple first doped regions 122 of the second PIN diode 110 and to the PAD node 136 through the frontside conductive layer tracks 140a-140f. The second BEOL resistor 112 includes the first end portion 112a connected to a second portion 112b through a frontside conductive layer track 144, which is connected to a VSS node 146 through a frontside conductive layer track 148. The VSS node 146 includes two frontside conductive layer tracks connected to each other through frontside conductive layer tracks 150a-150f and 152 and to the second doped regions 124 through the frontside conductive layer tracks 150a-150f. The multiple second doped regions 124 are electrically connected to each other and electrically connected to the VSS backside power contact 126 through backside vias (VBs) and backside conductive layer tracks. In some embodiments, the second BEOL resistor 112 including 112a and 112b, and the VSS node 146 are made from frontside conductive layer tracks, such as metal 4 conductive layer tracks.

In some embodiments, the first end portion 108a of the first BEOL resistor 108 is one of a stress pin or a sense pin and the PAD node 136 is another one of the stress pin or the sense pin for sensing the resistance of the first BEOL resistor 108. The first BEOL resistor 108 is stressed, i.e., has a voltage and/or current applied, and sensed, i.e., has the resistance measured, through the stress pin and the sense pin, respectively. In some embodiments, the PAD node 136 or the first end portion 112a of the second first BEOL resistor 112 is one of a stress pin or a sense pin and the VSS node 146 is another one of the stress pin or the sense pin for sensing the resistance of the second BEOL resistor 112. The second BEOL resistor 112 is stressed, i.e., has a voltage and/or current applied, and sensed, i.e., has the resistance measured, through the stress pin and the sense pin, respectively. In some embodiments, the stress pin and the sense pin are connected to an internal circuit of the IC for measuring the resistance of the first BEOL resistor 108 and/or the second BEOL resistor 112 and the temperature of the IC. In some embodiments, the first BEOL resistor 108 and/or the second BEOL resistor 112 are stressed and sensed through an external circuit connected to the backside pad contact 120 and the VDD/VSS backside power contacts 188 and 126.

The device 100 integrates the functions of ESD protection and thermal sensing into one compact device. The device 100 provides ESD protection through backside contacts and thermal sensing through frontside stress and sense pin contacts, independently, which increases the accuracy of the resistance and temperature measurements. Also, most of the first BEOL resistor 108 is situated in the footprint 128 of the first PIN diode 106, such that at least a portion of the first BEOL resistor 108 is situated within the footprint 128 of the first PIN diode 106, which reduces the footprint, i.e., the area of the device 100, on the IC. Also, most of the second BEOL resistor 112 is situated in the footprint 130 of the second PIN diode 110, such that at least a portion of the first BEOL resistor 112 is situated within the footprint 130 of the second PIN diode 110, which reduces the footprint, i.e., the area of the device 100, on the IC.

FIG. 5 is a diagram schematically illustrating a plan layout of an ESD protection and thermal sensing device 160, in accordance with some embodiments. The device 160 includes a PIN diode matrix 162 having a PIN diode matrix footprint 164. In some embodiments, the device 160 is like the device 100 of FIG. 4. In some embodiments, the PIN diode matrix 162 is like the PIN diode matrix 102. In some embodiments, the PIN diode matrix footprint 164 is like the PIN diode matrix footprint 104.

The PIN diode matrix 162 includes a first PIN diode 166 and a second PIN diode 168. In some embodiments, the first PIN diode 166 is like the first PIN diode 106 and the second PIN diode 168 is like the second PIN diode 110.

The device 160 includes a first BEOL resistor 170 that is connected to the first PIN diode 166 through frontside conductive layer tracks (not shown for clarity), and a second BEOL resistor 172 that is connected to the second PIN diode 168 through frontside conductive layer tracks (not shown for clarity). The first PIN diode 166 and the second PIN diode 168 provide ESD protection for the device 160 including the first BEOL resistor 170 and the second BEOL resistor 172. Each of the first BEOL resistor 170 and the second BEOL resistor 172 is a thermal sensing device or thermal sensor. The first BEOL resistor 170 includes a first portion 170a connected to a second portion 170b through a frontside conductive layer track 174, and the second BEOL resistor 172 includes a first portion 172a connected to a second portion 172b through a frontside conductive layer track 176. Also, the second portion 170b is connected to the first portion 172a and to a PAD node 178 through a frontside conductive layer track 180. In some embodiments, the first BEOL resistor 170 is like the first BEOL resistor 108 and the second BEOL resistor 172 is like the second BEOL resistor 112. In some embodiments, the first BEOL resistor 170, including 170a and 170b, and the second BEOL resistor 172, including 172a and 172b, are made from frontside conductive layer tracks, such as metal 4 conductive layer tracks.

The first BEOL resistor 170 is situated in the first PIN diode 166, such that at least a portion of the first BEOL resistor 170 is situated within a footprint 182 of the first PIN diode 166. The second BEOL resistor 172 is situated in the second PIN diode 168, such that at least a portion of the second BEOL resistor 172 is situated within a footprint 184 of the second PIN diode 168. In addition, each of the first BEOL resistor 170 and the second BEOL resistor 172 is situated in the PIN diode matrix footprint 164. In some embodiments, by integrating or having at least portions of the first and second BEOL resistors 170 and 172 in the footprints of the first and second PIN diodes 166 and 168, the area of the device layout on the IC is reduced up to 50%, as compared to having the first and second BEOL resistors 170 and 172 at the sides of the first and second PIN diodes 166 and 168.

In some embodiments, the first portion 170a of the first BEOL resistor 170 is one of a stress pin or a sense pin and the PAD node 178 is another one of the stress pin or the sense pin for sensing the resistance of the first BEOL resistor 170. The first BEOL resistor 170 is stressed, i.e., has a voltage and/or current applied, and sensed, i.e., has the resistance measured, through the stress pin and the sense pin, respectively. In some embodiments, the PAD node 178 or the first portion 172a of the second BEOL resistor 172 is one of a stress pin or a sense pin and the second portion 172b is another one of the stress pin or the sense pin for sensing the resistance of the second BEOL resistor 172. The second BEOL resistor 172 is stressed, i.e., has a voltage and/or current applied, and sensed, i.e., has the resistance measured, through the stress pin and the sense pin, respectively.

In some embodiments, the stress pin and the sense pin are connected to an internal circuit of the IC, such as the control circuit 30, for measuring the resistance of the first BEOL resistor 170 and/or the second BEOL resistor 172 and determining the temperature of the IC. In some embodiments, the first BEOL resistor 170 and/or the second BEOL resistor 172 are stressed and sensed through an external circuit.

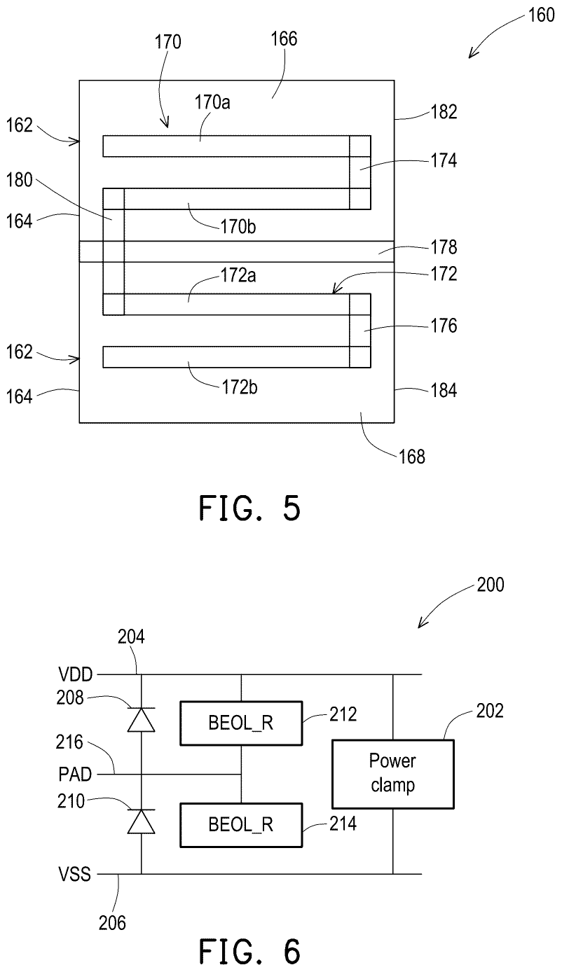

FIG. 6 is a diagram schematically illustrating an ESD protection and thermal sensing device 200 that includes a power clamp 202, in accordance with some embodiments. The power clamp 202 is connected on one side to a VDD backside power contact 204 and on another side to a VSS backside power contact 206. In some embodiments, the ESD protection and thermal sensing device 200 is like the ESD protection and thermal sensing device 40 of FIG. 2, except it also includes the power clamp 202. In some embodiments, the device 200 is part of an IC, such as the IC 20 of FIG. 1. In some embodiments, the device 200 is like the first device 26 (shown in FIG. 1). In some embodiments, the device 200 is like the second device 28 (shown in FIG. 1).

The device 200 includes the power clamp 202, a first PIN diode 208, a second PIN diode 210, a first BEOL resistor 212, and a second BEOL resistor 214. In some embodiments the first PIN diode 208 is like the first PIN diode 42 (shown in FIG. 2). In some embodiments the second PIN diode 210 is like the second PIN diode 44 (shown in FIG. 2). In some embodiments, the first BEOL resistor 212 is like the first sensor 46 (shown in FIG. 2). In some embodiments, the second BEOL resistor 214 is like the second sensor 48 (shown in FIG. 2).

The first PIN diode 208 includes a cathode connected to the VDD backside power contact 204 and an anode connected to a PAD backside contact 216. The first PIN diode 208 shunts ESD events from the PAD backside contact 216 to the VDD backside power contact 204 and from the VDD backside power contact 204 to the PAD backside contact 216. In some embodiments, the cathode of the first PIN diode 208 is an N+ region. In some embodiments, the anode of the first PIN diode 208 is a P+ region.

The second PIN diode 210 includes a cathode connected to the PAD backside contact 216 and an anode connected to the VSS backside power contact 206. The second PIN diode 210 shunts ESD events from the PAD backside contact 216 to the VSS backside power contact 206 and from the VSS backside power contact 206 to the PAD backside contact 216. In some embodiments, the cathode of the second PIN diode 210 is an N+ region. In some embodiments, the anode of the second PIN diode 210 is a P+ region.

The first BEOL resistor 212 has one end connected to the VDD backside power contact 204 and another end connected to the PAD backside contact 216. One end of the first BEOL resistor 212 is connected to one of a stress pin or a sense pin and the other end of the first BEOL resistor 212 is connected to the other one of the stress pin or the sense pin. A voltage and/or current is applied to the stress pin of the first BEOL resistor 212 and a measurement is obtained at the sense pin of the first BEOL resistor 212 to determine the temperature of the device 200 and the IC. For example, a voltage and/or current is applied at the stress pin and a measurement of the resistance of the first BEOL resistor 212 is obtained at the sense pin. From this resistance measurement, a control circuit, such as the control circuit 30 in the IC 20, determines the temperature of the device 200 and the IC 20.

The second BEOL resistor 214 has one end connected to the PAD backside contact 216 and another end connected to the VSS backside power contact 206. One end of the second BEOL resistor 214 is connected to one of a stress pin or a sense pin and the other end of the second BEOL resistor 214 is connected to the other one of the stress pin or the sense pin. A voltage and/or current is applied to the stress pin of the second BEOL resistor 214 and a measurement is obtained at the sense pin of the second BEOL resistor 214 to determine the temperature of the device 200 and the IC 20. For example, a voltage and/or current is applied at the stress pin and a measurement of the resistance of the second BEOL resistor 214 is obtained at the sense pin. From this resistance measurement, a control circuit, such as the control circuit 30 in the IC 20, determines the temperature of the device 200 and the IC 20. In some embodiments, the resistance values of the first BEOL resistor 212 and the second BEOL resistor 214 are combined to determine the temperature of the device 200 and/or the IC.

The power clamp 202 provides ESD protection from ESD events by shunting the ESD events through the power clamp 202 between the VDD backside power contact 204 and the VSS backside power contact 206. The ESD events flow through the first PIN diode 208, the second PIN diode 210, and the power clamp 202, which protects the first BEOL resistor 212 and the second BEOL resistor 214. In some embodiments, the power clamp 202 includes an ESD detection circuit, an active trigger circuit, and a big field effect transistor (bigFET) for shunting the current and/or voltage of the ESD events.

The device 200 integrates the functions of ESD protection and thermal sensing into one device 200 that is configured to provide the ESD protection and thermal sensing functions independently. This results in increasing the accuracy of the resistance and temperature measurements.

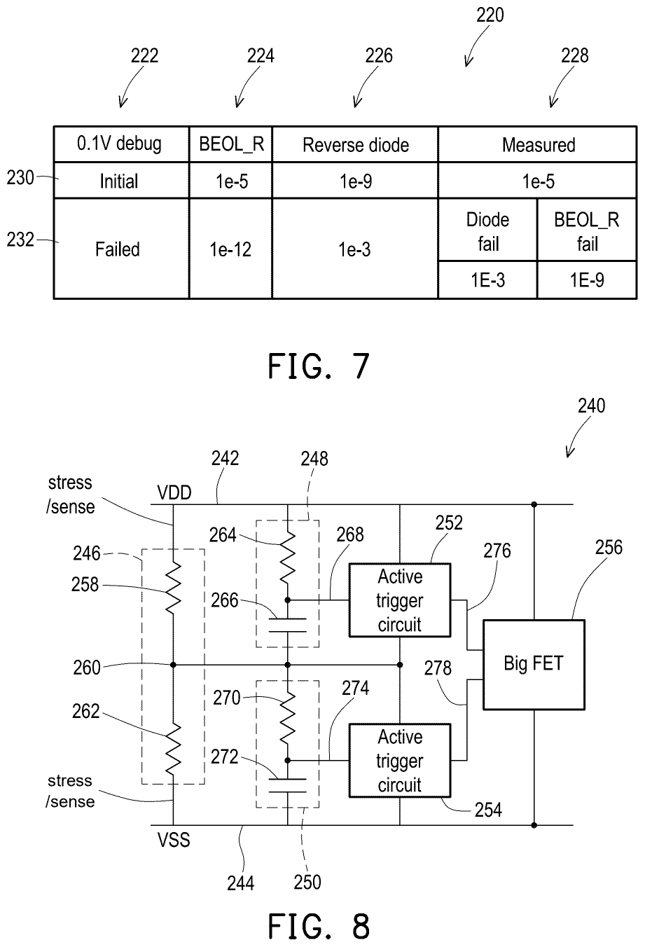

FIG. 7 is a diagram schematically illustrating a table 220 for verifying the status of the BEOL resistors and the PIN diodes in the ESD protection and thermal sensing devices, such as the devices 40, 60, 100, 160, and 200, in accordance with some embodiments. The table 220 includes columns for a 0.1V (volt) debug 222, BEOL resistor currents 224, reverse diode currents 226, and measured currents 228. In the proposed scheme, diode failures for small reverse diode leaks are detectable and the operational voltage of 0.1V is rather small to improve reliability.

The first row 230 indicates initial values, i.e., values for the components if the components are functioning properly. In the first row 230, the BEOL resistor currents 224 will be about 1e-5 amperes (amps) and the reverse diode currents 226 will be about 1e-9 amps, which results in measured currents 228 of about 1e-5 across a BEOL resistor and a reverse biased PIN diode.

The second row 232 indicates failed values, i.e., values for the components if the components are not functioning properly. In the second row 232, the BEOL resistor currents 224 will be about 1e-12 amps and the reverse diode currents 226 will be about 1e-3 amps, which results in measured currents 228 of about 1e-3 if a diode fails and about 1e-9 if a BEOL resistor fails, when measured across a BEOL resistor and a reverse biased PIN diode.

FIG. 8 is a diagram schematically illustrating a power clamp device 240 that is an ESD protection and thermal sensing device, in accordance with some embodiments. The device 240 is electrically connected on one side to a VDD backside power contact 242 and on another side to a VSS backside power contact 244. In some embodiments, the device 240 is part of an IC, such as the IC 20 of FIG. 1. In some embodiments, the device 240 is like the first device 26 (shown in FIG. 1). In some embodiments, the device 240 is like the second device 28 (shown in FIG. 1).

The device 240 includes a power clamp voltage divider 246, a first ESD detection circuit 248, a second ESD detection circuit 250, a first active trigger circuit 252, a second active trigger circuit 254, and a bigFET circuit 256. In some embodiments, the device 240 is an ESD protection and thermal sensing device for a core region, such as the core region 22 (shown in FIG. 1). In some embodiments, the device 240 is a 1.2V ESD power clamp device for core-only operation with the power clamp voltage divider 246.

The power clamp voltage divider 246 includes a first BEOL resistor 258 having a first end electrically connected to a VDD backside power contact 242 and a second end electrically connected to a voltage divider node 260, and a second BEOL resistor 262 having a third end electrically connected to the voltage divider node 260 and a fourth end electrically connected to a VSS backside power contact 244. The power clamp voltage divider 246, including the first BEOL resistor 258 and the second BEOL resistor 262, is a frontside thermal sensor having one of a stress or sense pin electrically connected to the first end of the first BEOL resistor 258 and the VDD backside power contact 242 and another one of the stress or sense pin electrically connected to the fourth end of the second BEOL resistor 262 and the VSS backside power contact 244. The resistance of the first BEOL resistor 258 and the second BEOL resistor 262 can be configured to meet device 240 leakage requirements without degrading the sensitivity of the thermal sensor. In some embodiments, the voltage divider node 260 is a frontside PAD contact. In some embodiments, the voltage divider node 260 is electrically connected to a backside PAD contact.

A voltage and/or current is applied to the stress pin and a measurement is obtained at the sense pin to determine the temperature of the device 240 and the IC, such as the IC 20 of FIG. 1. For example, a voltage and/or current is applied at the stress pin and a measurement of the resistance of the first BEOL resistor 258 and the second BEOL resistor 262 is obtained at the sense pin. From this resistance measurement, a control circuit, such as the control circuit 30 in the IC 20, determines the temperature of the device 240 and the IC 20. In some embodiments, the resistance values of the first BEOL resistor 258 and the second BEOL resistor 262 are obtained separately to determine the temperature of the device 240 and/or the IC 20.

The first ESD detection circuit 248 includes a first resistor 264 and a first capacitor 266. The first ESD detection circuit 248, including the first resistor 264 and the first capacitor 266, is a frontside ESD detection circuit 248. One end of the first resistor 264 is electrically connected to the VDD backside power contact 242 and another end of the first resistor 264 is electrically connected to one end of the first capacitor 266 and to the first active trigger circuit 252 by conductive path 268. Another end of the first capacitor 266 is electrically connected to the voltage divider node 260.

The second ESD detection circuit 250 includes a second resistor 270 and a second capacitor 272. The second ESD detection circuit 250, including the second resistor 270 and the second capacitor 272, is a frontside ESD detection circuit 250. One end of the second resistor 270 is electrically connected to the voltage divider node 260 and the first capacitor 266 and another end of the second resistor 270 is electrically connected to one end of the second capacitor 272 and to the second active trigger circuit 254 by conductive path 274. Another end of the second capacitor 272 is electrically connected to the VSS backside power contact 244.

The first active trigger circuit 252 is electrically connected on one side to the VDD backside power contact 242 and on another side to the voltage divider node 260. The first active trigger circuit 252 receives an input on conductive path 268 and provides a first output to the bigFET 256 on first output conductive path 276. In some embodiments, the first active trigger circuit 252 includes metal-oxide-semiconductor field-effect transistors (MOSFETs) situated in a substate, such as the substrate 66 (shown in FIG. 3).

The second active trigger circuit 254 is electrically connected on one side to the voltage divider node 260 and on another side to the VSS backside power contact 244. The second active trigger circuit 254 receives an input on conductive path 274 and provides a second output to the bigFET 256 on second output conductive path 278. In some embodiments, the second active trigger circuit 254 includes MOSFETs situated in a substate, such as the substrate 66 (shown in FIG. 3).

The bigFET circuit 256 receives inputs from the first active trigger circuit 252 and the second active trigger circuit 254. The bigFET circuit 256 is electrically connected on one side to the VDD backside power contact 242 and on another side to the VSS backside power contact 244. In some embodiments, the bigFET circuit 256 is electrically connected on one side to the VDD backside power contact 242 through a first backside via VBB and on another side to the VSS backside power contact 244 through a second backside via VBB. In some embodiments, the bigFET circuit 256 includes one or more MOSFETs situated in a substate, such as the substrate 66 (shown in FIG. 3).

In operation of the ESD protection circuit, an ESD event is detected by the first ESD detection circuit 248 and/or the second ESD detection circuit 250. The first active trigger circuit 252 is activated if the ESD event is detected by the first ESD detection circuit 248, and the second active trigger circuit 254 is activated if the ESD event is detected by the second ESD detection circuit 250. The activated trigger circuit activates the bigFET circuit 256 to discharge the ESD event through the bigFET circuit 256 to the VDD backside power contact 242 and/or to the VSS backside power contact 244.

The status of the components of the device 240, including the first and second BEOL resistors 258 and 262 and the bigFET circuit 256, are determined like in FIG. 7. The values for the device 240 may be different than the values in the table 220, however, the measurements are similar.

As depicted in FIG. 7, the first row 230 indicates initial values, i.e., values for the components if the components are functioning properly, and the second row 232 indicates failed values, i.e., values for the components if the components are not functioning properly. In the first row 230, the BEOL resistor currents will be a first value and the bigFET circuit leakage current will be a second value that is smaller than the first value, which results in measured currents of the first value across the BEOL resistors 258 and 262 and the bigFET circuit 256. In the second row 232, the BEOL resistor currents will be a third value that is smaller than the second value and the bigFET circuit leakage current will be a fourth value that is larger than the first value, which results in measured currents of the fourth value if the bigFET circuit 256 fails and of the second value if the BEOL resistors fail, when measured across the BEOL resistors 258 and 262 and the bigFET circuit 256.

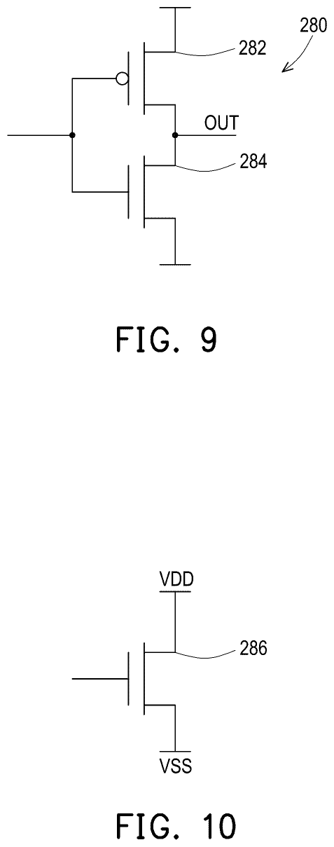

FIG. 9 is a diagram schematically illustrating an active trigger circuit 280, in accordance with some embodiments. The active trigger circuit 280 includes a PMOS transistor 282 electrically connected in series to an NMOS transistor 284 at output OUT.

In some embodiments, the first active trigger circuit 252 is like the active trigger circuit 280 that includes the PMOS transistor 282 having one drain/source region electrically connected in series to one drain/source region of the NMOS transistor 284 at the output OUT, which is electrically connected to the bigFET circuit 256. The other drain/source region of the PMOS transistor 282 is electrically connected to the VDD backside power contact 242 and the other drain/source region of the NMOS transistor 284 is electrically connected to the voltage divider node 260. The gates of the PMOS transistor 282 and the NMOS transistor 284 are electrically connected to each other and to the first ESD detection circuit 248.

In some embodiments, the second active trigger circuit 254 is like the active trigger circuit 280 that includes the PMOS transistor 282 having one drain/source region electrically connected in series to one drain/source region of the NMOS transistor 284 at the output OUT, which is electrically connected to the bigFET circuit 256. The other drain/source region of the PMOS transistor 282 is electrically connected to the voltage divider node 260 and the other drain/source region of the NMOS transistor 284 is electrically connected to the VSS backside power contact 244. The gates of the PMOS transistor 282 and the NMOS transistor 284 are electrically connected to each other and to the second ESD detection circuit 250.

FIG. 10 is a diagram schematically illustrating a bigFET 286, in accordance with some embodiments. The bigFET 286 is a MOSFET. In some embodiments, the bigFET 286 is like the bigFET circuit 256.

In some embodiments, the bigFET 286 is electrically connected on one side to the VDD backside power contact 242 and on another side to the VSS backside power contact 244. In some embodiments, the bigFET 286 is electrically connected on one side to the VDD backside power contact 242 through a first backside via VBB and on another side to the VSS backside power contact 244 through a second backside via VBB.

The bigFET 286 is configured to handle higher levels of ESD currents as compared to traditional ESD protection circuits. In some embodiments, the bigFET 286 is a power MOSFET with larger dimensions (hence the term “bigFET”) to handle higher currents. These MOSFETs have low resistances to allow higher discharge currents to flow through them without causing damage to the protected devices.

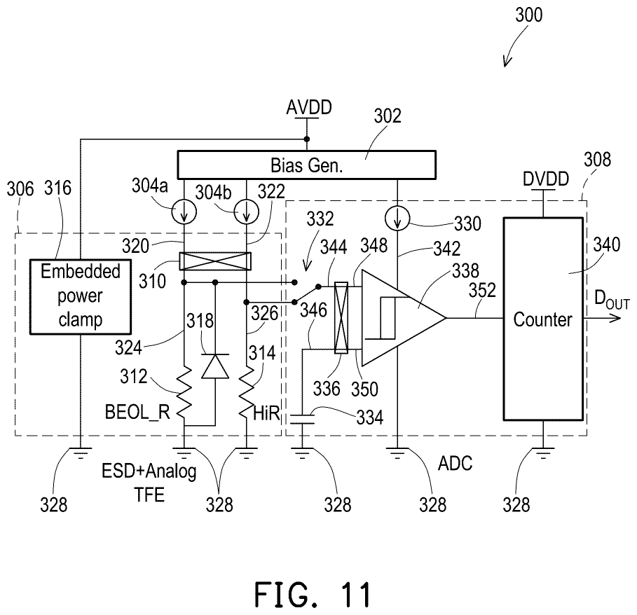

FIG. 11 is a diagram schematically illustrating an ESD protection and thermal sensing device 300, in accordance with some embodiments. The device 300 includes one or more ESD protection circuits or devices integrated into an analog thermal front end (TFE) of a thermal sensor, which reduces the area of the device 300. Also, the ESD discharge paths do not affect the thermal sensing operation. In some embodiments, the device 300 is part of an IC, such as the IC 20 of FIG. 1.

The device 300 includes a bias generator 302, two current sources 304a and 304b, an ESD protection and analog TFE 306, and an analog-to-digital converter (ADC) 308. The bias generator 302 is electrically connected to an analog power supply voltage AVDD and to the two current sources 304a and 304b that provide current to the ESD protection and analog TFE 306.

The ESD protection and analog TFE 306 includes a first chopper circuit 310, a BEOL resistor 312, a high resistance reference resistor 314, and at least one of an embedded power clamp 316 and a diode clamp 318, such as a PIN diode clamp, for ESD protection. The two current sources 304a and 304b are electrically connected to the first chopper circuit 310 by conductive paths 320 and 322. Also, one output of the first chopper circuit 310 is electrically connected to the BEOL resistor 312 by conductive path 324 and another output of the first chopper circuit 310 is electrically connected to the high resistance reference resistor 314 by conductive path 326. Each of the BEOL resistor 312 and the high resistance reference resistor 314 is electrically connected to a reference 328, such as ground.

The embedded power clamp 316 is electrically connected to the analog power supply voltage AVDD and to the reference 328. Also, the diode clamp 318 has a cathode electrically connected to one end of the BEOL resistor 312 and an anode electrically connected to the other end of the BEOL resistor 312 and to the reference 328. Each of the embedded power clamp 316 and the diode clamp 318 is configured to protect the device 300 from ESD events. In some embodiments, the device 300 only includes the embedded power clamp 316. In some embodiments, the device 300 only includes the diode clamp 318.

The two current sources 304a and 304b provide current to the first chopper circuit 310 that provides current to the BEOL resistor 312 and the high resistance reference resistor 314. The voltages on the BEOL resistor 312 and the high resistance reference resistor 314 are transmitted to the ADC 308 for determining the temperature of the device 300 and the IC.

The ADC 308 includes a third current source 330, a switch 332, a capacitor 334, a second chopper 336, a Schmidt trigger 338, and a counter 340. The third current source 330 is electrically connected to the bias generator 302 and electrically connected to the Schmidt trigger 338 by conductive path 342, and another side of the Schmidt trigger 338 is electrically connected to the reference 328. Also, one side of the counter 340 is electrically connected to a digital voltage power supply DVDD and another side of the counter 340 is electrically connected to the reference 328.

The switch 332 has one input electrically connected to the BEOL resistor 312 by conductive path 324 and another input electrically connected to the high resistance reference resistor 314 by conductive path 326. An output of the switch 332 is electrically connected to one input of the second chopper 336 by conductive path 344. Another input of the second chopper 336 is electrically connected to one side of the capacitor 334 by conductive path 346 and the other side of the capacitor 334 is electrically connected to the reference 328, such as ground.

One input of the second chopper 336 receives the voltages on the BEOL resistor 312 and the high resistance reference resistor 314 and another input of the second chopper 336 is electrically connected to the capacitor 334. The second chopper 336 is electrically connected to the Schmidt trigger 338 by conductive paths 348 and 350 and an output of the Schmidt trigger is electrically connected to the counter 340 by conductive path 352. The second chopper 336 transmits inputs to the Schmidt trigger 338 that transmits signals to the counter 340. The counter 340 counts to provide an output Dout that indicates the temperature of the device 300 and the IC.

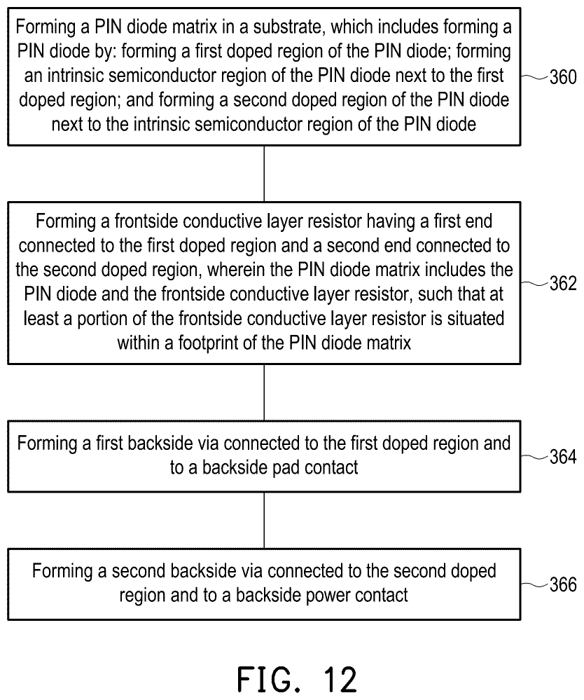

FIG. 12 is a diagram schematically illustrating a method of manufacturing an ESD protection and thermal sensing device, in accordance with some embodiments. In some embodiments, the ESD protection and thermal sensing device is like one of the devices 20, 40, 60, 100, 160, 200 described herein.

At 360, the method includes forming a PIN diode matrix in a substrate, which includes forming a PIN diode by: forming a first doped region of the PIN diode; forming an intrinsic semiconductor region of the PIN diode next to the first doped region; and forming a second doped region of the PIN diode next to the intrinsic semiconductor region of the PIN diode. In some embodiments, the PIN diode matrix is like the PIN diode matrix 102 (shown in FIG. 4) and the substrate is like the substrate 66 (shown in FIG. 3). In some embodiments, the PIN diode is like the PIN diode 62 (shown in FIG. 3). In some embodiments the first doped region is like the first doped region 68 (shown in FIG. 3), the second doped region is like the second doped region 70 (shown in FIG. 3), and the intrinsic semiconductor region is like the intrinsic semiconductor region 72 (shown in FIG. 3).

In some embodiments, forming the first doped region includes forming a P+ region and forming the second doped region includes forming an N+ region connected to a VDD backside power contact. In some embodiments, forming the first doped region includes forming an N+ region and forming the second doped region includes forming a P+ region connected to a VSS backside power contact.

At 362, the method includes forming a frontside conductive layer resistor having a first end connected to the first doped region and a second end connected to the second doped region, wherein the PIN diode matrix includes the PIN diode and the frontside conductive layer resistor, such that at least a portion of the frontside conductive layer resistor is situated within a footprint of the PIN diode matrix. In some embodiments, the frontside conductive layer resistor is like the BEOL resistor 64 (shown in FIG. 3). In some embodiments, the frontside conductive layer resistor is like the BEOL resistor 108 (shown in FIG. 4) or the BEOL resistor 112 (shown in FIG. 4). In some embodiments, the PIN diode matrix footprint is like the PIN diode matrix footprint 104 (shown in FIG. 4).

At 364, the method includes forming a first backside via connected to the first doped region and to a backside pad contact and, at 366, the method includes forming a second backside via connected to the second doped region and to a backside power contact. In some embodiments, the first backside via is like the first backside via VB 74. In some embodiments, the second backside via is like the second backside via VB 80.

In some embodiments, the method includes forming a first connection of frontside conductive layers from the first doped region to the first end of the frontside conductive layer resistor and forming a second connection of the frontside conductive layers from the second doped region to the second end of the frontside conductive layer resistor. In some embodiments, the method includes forming a sense pin of frontside conductive layers connected to the first end of the frontside conductive layer resistor and forming a stress pin of the frontside conductive layers connected to the second end of the frontside conductive layer resistor, wherein the frontside conductive layer resistor includes a resistance that is measured by applying a voltage or current to the stress pin and measuring the resistance through the sense pin to measure a temperature.

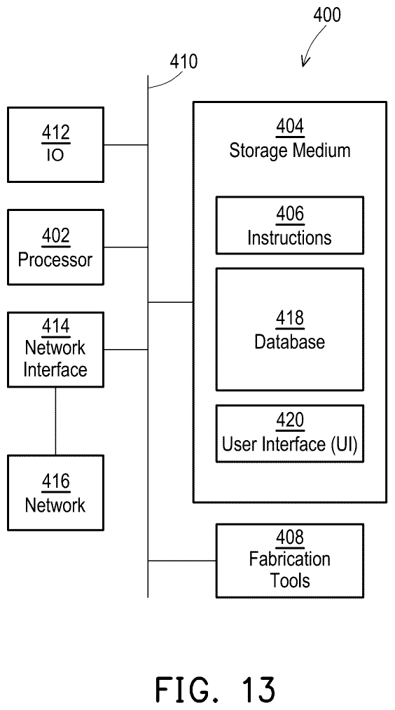

FIG. 13 is a block diagram schematically illustrating an example of a computer system 400 configured to provide the devices, including electronic devices and semiconductor devices, and methods of the current disclosure, in accordance with some embodiments. Some or all the design, layout, and manufacture of the semiconductor devices, also referred to as semiconductor circuits, can be performed by or with the aid of the computer system 400. Also, some or all the design, layout, and manufacture of the devices including electronic devices can be performed by or with the aid of the computer system 400. In some embodiments, the computer system 400 includes an electronic design automation (EDA) system. In some embodiments, the semiconductor devices are ICs.

In some embodiments, the system 400 is a general-purpose computing device including a processor 402 and a non-transitory, computer-readable storage medium 404. The computer-readable storage medium 404 may be encoded with, e.g., store, computer program code such as executable instructions 406. Execution of the instructions 406 by the processor 402 provides (at least in part) a design tool that implements a portion or all the functions of the system 400, such as pre-layout simulations, post-layout simulations, routing, rerouting, and final layout for manufacturing. Further, fabrication tools 408 are included to further layout and physically implement the design and manufacture of the semiconductor devices. In some embodiments, execution of the instructions 406 by the processor 402 provides (at least in part) a design tool that implements a portion or all the functions of the system 400. In some embodiments, the system 400 includes a commercial router. In some embodiments, the system 400 includes an automatic place and route (APR) system.

The processor 402 is electrically coupled to the computer-readable storage medium 404 by a bus 410 and to an I/O interface 412 by the bus 410. A network interface 414 is also electrically connected to the processor 402 by the bus 410. The network interface 414 is connected to a network 416, so that the processor 402 and the computer-readable storage medium 404 can connect to external elements using the network 416. The processor 402 is configured to execute the computer program code or instructions 406 encoded in the computer-readable storage medium 404 to cause the system 400 to perform a portion or all the functions of the system 400, such as providing the semiconductor devices and methods of the current disclosure and other functions of the system 400. In some embodiments, the processor 402 is a central processing unit (CPU), a multi-processor, a distributed processing system, an application specific integrated circuit (ASIC), and/or a suitable processing unit.

In some embodiments, the computer-readable storage medium 404 is an electronic, magnetic, optical, electromagnetic, infrared, and/or semiconductor system or apparatus or device. For example, the computer-readable storage medium 404 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 404 can include a compact disk read only memory (CD-ROM), a compact disk read/write memory (CD-R/W), and/or a digital video disc (DVD).

In some embodiments, the computer-readable storage medium 404 stores computer program code or instructions 406 configured to cause the system 400 to perform a portion or all the functions of the system 400. In some embodiments, the computer-readable storage medium 404 also stores information which facilitates performing a portion or all the functions of the system 400. In some embodiments, the computer-readable storage medium 404 stores a database 418 that includes one or more of component libraries, digital circuit cell libraries, and databases.

The system 400 includes the I/O interface 412, which is coupled to external circuitry. In some embodiments, the I/O interface 412 includes a keyboard, keypad, mouse, trackball, trackpad, touchscreen, and/or cursor direction keys for communicating information and commands to the processor 402.

The network interface 414 is coupled to the processor 402 and allows the system 400 to communicate with the network 416, to which one or more other computer systems are connected. The network interface 414 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 400 can be performed in two or more systems that are like system 400.

The system 400 is configured to receive information through the I/O interface 412. The information received through the I/O interface 412 includes one or more of instructions, data, design rules, libraries of components and cells, and/or other parameters for processing by the processor 402. The information is transferred to the processor 402 by the bus 410. Also, the system 400 is configured to receive information related to a user interface (UI) through the I/O interface 412. This UI information can be stored in the computer-readable storage medium 404 as a UI 420.

In some embodiments, a portion or all the functions of the system 400 are implemented via a standalone software application for execution by a processor. In some embodiments, a portion or all the functions of the system 400 are implemented in a software application that is a part of an additional software application. In some embodiments, a portion or all the functions of the system 400 are implemented as a plug-in to a software application. In some embodiments, at least one of the functions of the system 400 is implemented as a software application that is a portion of an EDA tool. In some embodiments, a portion or all the functions of the system 400 are implemented as a software application that is used by the system 400. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 400 include fabrication tools 408 for implementing the manufacturing processes of the system 400. For example, based on the final layout, photolithographic masks may be generated, which are used to fabricate the semiconductor device by the fabrication tools 408.

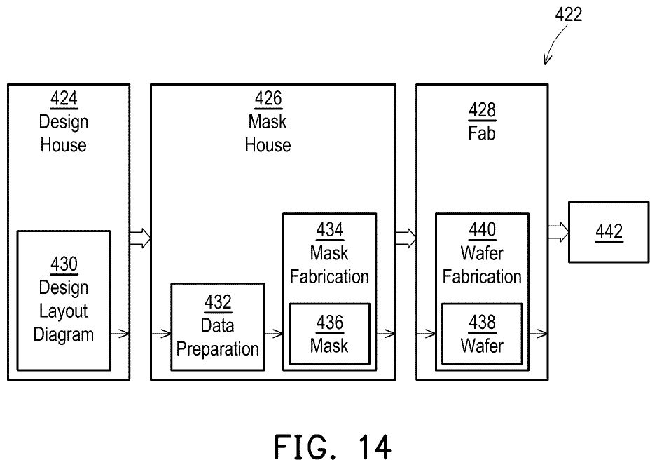

Further aspects of device fabrication are disclosed in conjunction with FIG. 14, which is a block diagram of a semiconductor device manufacturing system 422 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 422.

In FIG. 14, the semiconductor device manufacturing system 422 includes entities, such as a design house 424, a mask house 426, and a semiconductor device manufacturer/fabricator (“Fab”) 428, that interact with one another in the design, development, and manufacturing cycles and/or services related to manufacturing a semiconductor device, such as the semiconductor devices described herein. The entities in the system 422 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 424, the mask house 426, and the semiconductor device fab 428 are owned by a single larger company. In some embodiments, two or more of the design house 424, the mask house 426, and the semiconductor device fab 428 coexist in a common facility and use common resources.

The design house (or design team) 424 generates a semiconductor device design layout diagram 430. The semiconductor device design layout diagram 430 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 430 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 424 implements a design procedure to form a semiconductor device design layout diagram 430. The semiconductor device design layout diagram 430 is presented in one or more data files having information of the geometrical patterns. For example, semiconductor device design layout diagram 430 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 426 includes data preparation 432 and mask fabrication 434. The mask house 426 uses the semiconductor device design layout diagram 430 to manufacture one or more masks 436 to be used for fabricating the various layers of the semiconductor device or semiconductor structure. The mask house 426 performs mask data preparation 432, where the semiconductor device design layout diagram 430 is translated into a representative data file (RDF). The mask data preparation 432 provides the RDF to the mask fabrication 434. The mask fabrication 434 includes a mask writer that converts the RDF to an image on a substrate, such as a mask (reticle) 436 or a semiconductor wafer 438. The design layout diagram 430 is manipulated by the mask data preparation 432 to comply with characteristics of the mask writer and/or criteria of the semiconductor device fab 428. In FIG. 14, the mask data preparation 432 and the mask fabrication 434 are illustrated as separate elements. In some embodiments, the mask data preparation 432 and the mask fabrication 434 can be collectively referred to as mask data preparation.

In some embodiments, the mask data preparation 432 includes an optical proximity correction (OPC) which uses lithography enhancement techniques to compensate for image errors, such as those that can arise from diffraction, interference, other process effects and the like. The OPC adjusts the semiconductor device design layout diagram 430. In some embodiments, the mask data preparation 432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 432 includes a mask rule checker (MRC) that checks the semiconductor device design layout diagram 430 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 430 to compensate for limitations during the mask fabrication 434, which may undo part of the modifications performed by OPC to meet mask creation rules.

In some embodiments, the mask data preparation 432 includes lithography process checking (LPC) that simulates processing that will be implemented by the semiconductor device fab 428. LPC simulates this processing based on the semiconductor device design layout diagram 430 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 430.

The above description of mask data preparation 432 has been simplified for the purposes of clarity. In some embodiments, data preparation 432 includes additional features such as a logic operation (LOP) to modify the semiconductor device design layout diagram 430 according to manufacturing rules. Additionally, the processes applied to the semiconductor device design layout diagram 430 during data preparation 432 may be executed in a variety of different orders.

After the mask data preparation 432 and during the mask fabrication 434, a mask 436 or a group of masks 436 are fabricated based on the modified semiconductor device design layout diagram 430. In some embodiments, the mask fabrication 434 includes performing one or more lithographic exposures based on the semiconductor device design layout diagram 430. In some embodiments, an electron-beam (e-beam) or a mechanism of multiple e-beams is used to form a pattern on a mask (photomask or reticle) 436 based on the modified semiconductor device design layout diagram 430. The mask 436 can be formed in various technologies. In some embodiments, the mask 436 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 436 includes a transparent substrate (e.g., fused quartz) and an opaque material (e.g., chromium) coated in the opaque regions of the binary mask. In another example, the mask 436 is formed using a phase shift technology. In a phase shift mask (PSM) version of the mask 436, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 434 is used in a variety of processes. For example, such a mask(s) is used in an ion implantation process to form various doped regions in the semiconductor wafer 438, in an etching process to form various etching regions in the semiconductor wafer 438, and/or in other suitable processes.

The semiconductor device fab 428 includes wafer fabrication 440. The semiconductor device fab 428 is a semiconductor device fabrication business that includes one or more manufacturing facilities for the fabrication of a variety of different semiconductor device products. In some embodiments, the semiconductor device fab 428 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 428 uses the mask(s) 436 fabricated by the mask house 426 to fabricate the semiconductor structures or semiconductor devices 442 of the current disclosure. Thus, the semiconductor device fab 428 at least indirectly uses the semiconductor device design layout diagram 430 to fabricate the semiconductor structures or semiconductor devices 442 of the current disclosure. Also, the semiconductor wafer 438 includes a silicon substrate or other proper substrate having material layers formed thereon, and the semiconductor wafer 438 further includes one or more of various doped regions, dielectric features, multilevel interconnects, and the like (formed at subsequent manufacturing steps). In some embodiments, the semiconductor wafer 438 is fabricated by the semiconductor device fab 428 using the mask(s) 436 to form the semiconductor structures or semiconductor devices 442 of the current disclosure. In some embodiments, the semiconductor device fabrication includes performing one or more lithographic exposures based at least indirectly on the semiconductor device design layout diagram 430.

Disclosed embodiments thus provide ESD protection and thermal sensing in a single device. In some embodiments, the ESD protection includes a PIN diode matrix in a substrate and at least one PIN diode in the PIN diode matrix for ESD protection. The thermal sensor includes at least one BEOL resistor having at least a portion of the BEOL resistor situated within a footprint of the at least one PIN diode. In some embodiments, the at least one BEOL resistor is part of the PIN diode matrix. In some embodiments, a stress pin and a sense pin are connected to the at least one BEOL resistor for sensing resistance and temperature of the at least one BEOL resistor.

Disclosed embodiments further include an ESD power clamp device that includes a power clamp voltage divider including a first BEOL resistor having a first end connected to a VDD power contact and a second end connected to a voltage divider node, and a second BEOL resistor having a third end connected to the voltage divider node and a fourth end connected to a VSS power contact. The ESD power clamp device includes an ESD detection circuit, an active trigger circuit, and a bigFET circuit connected on a first side to the VDD power contact and on a second side to the VSS power contact for ESD protection.

Further disclosed embodiments include integrating ESD protection into an analog TFE of a thermal sensor to improve performance and reduce the area for thermal sensing and ESD protection. The device includes an analog TFE that includes a BEOL resistor and a high resistance reference resistor for determining the temperature of the IC and an embedded power clamp and/or diode clamp for ESD protection.

Still further disclosed embodiments, include a method of manufacturing a device. The method includes forming a PIN diode matrix in a substrate, forming a frontside conductive layer resistor having a first end connected to a first doped region of a PIN diode and a second end connected to a second doped region of the PIN diode, wherein the PIN diode matrix includes the PIN diode and the frontside conductive layer resistor, such that at least a portion of the frontside conductive layer resistor is situated within a footprint of the PIN diode matrix, forming a first backside via connected to the first doped region and to a backside pad contact, and forming a second backside via connected to the second doped region and to a backside power contact.

Advantages of the disclosed embodiments include integrating thermal sensing and ESD protection in a single device, reducing the footprint of the device, and increasing the accuracy of the resistance and temperature measurements. Also, BEOL resistors embedded in PIN diodes and BEOL resistors integrated into power clamps are compatible with frontside/backside routing processes and frontside-only routing processes.

In accordance with some embodiments, a device includes a substrate and a first PIN diode for ESD protection situated in the substrate. The first PIN diode has a first region, a second region, and a first intrinsic semiconductor region situated between the first region and the second region. The device further includes a first backside via connected to the first region and to a backside pad contact, a second backside via connected to the second region and to a first backside power contact, and a first frontside conductive layer resistor for thermal sensing having a first end connected to the first region and a second end connected to the second region, where at least a portion of the first frontside conductive layer resistor is situated within a first footprint of the first PIN diode.

In accordance with further embodiments, an ESD power clamp device includes a power clamp voltage divider that includes a first frontside conductive layer resistor having a first end connected to a VDD power contact and a second end connected to a voltage divider node, and a second frontside conductive layer resistor having a third end connected to the voltage divider node and a fourth end connected to a VSS power contact. The device further includes a first ESD detection circuit connected to the VDD power contact and the voltage divider node, a first active trigger circuit connected to the first ESD detection circuit and to the VDD power contact and the voltage divider node, and a field effect transistor circuit connected to the first active trigger circuit and connected on a first side to the VDD power contact and on a second side to the VSS power contact. Where the power clamp voltage divider is a thermal sensor having one of a sense or stress pin at the VDD power contact and another one of the sense or stress pin at the VSS power contact.

In accordance with still further disclosed aspects, a method of manufacturing a device includes forming a PIN diode matrix in a substrate, which includes forming a PIN diode by forming a first doped region of the PIN diode, forming an intrinsic semiconductor region of the PIN diode next to the first doped region, and forming a second doped region of the PIN diode next to the intrinsic semiconductor region of the PIN diode. The method further includes forming a frontside conductive layer resistor having a first end connected to the first doped region and a second end connected to the second doped region, wherein the PIN diode matrix includes the PIN diode and the frontside conductive layer resistor, such that at least a portion of the frontside conductive layer resistor is situated within a footprint of the PIN diode matrix, forming a first backside via connected to the first doped region and to a backside pad contact, and forming a second backside via connected to the second doped region and to a backside power contact.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate;
a first PIN diode for electro-static discharge (ESD) protection situated in the substrate and having a first region, a second region, and a first intrinsic semiconductor region situated between the first region and the second region;
a first backside via connected to the first region and to a backside pad contact;
a second backside via connected to the second region and to a first backside power contact; and
a first frontside conductive layer resistor for thermal sensing having a first end connected to the first region and a second end connected to the second region,
wherein at least a portion of the first frontside conductive layer resistor is situated within a first footprint of the first PIN diode.

2. The device of claim 1, comprising a PIN diode matrix situated in the substrate and that includes the first PIN diode, wherein the first frontside conductive layer resistor is part of the PIN diode matrix.

3. The device of claim 1, wherein the first end of the first frontside conductive layer resistor is connected to the first region through frontside conductive layers and the second end of the first frontside conductive layer resistor is connected to the second region through the frontside conductive layers.

4. The device of claim 1, wherein the first region is a P+ region and the second region is an N+ region connected to a VDD backside power contact.

5. The device of claim 1, wherein the first region is an N+ region and the second region is a P+ region connected to a VSS backside power contact.

6. The device of claim 1, comprising a sense pin connected to the first end of the first frontside conductive layer resistor through the frontside conductive layers and a stress pin connected to the second end of the first frontside conductive layer resistor through the frontside conductive layers.

7. The device of claim 1, wherein the first frontside conductive layer resistor is configured to be stressed and sensed through the backside pad contact and the first backside power contact.

8. The device of claim 1, comprising:
a second PIN diode situated in the substrate and having a third region, a fourth region, and a second intrinsic semiconductor region situated between the third region and the fourth region;
a third backside via connected to the third region and to the backside pad contact;
a fourth backside via connected to the fourth region and to a second backside power contact that is different than the first backside power contact; and
a second frontside conductive layer resistor having a third end connected to the third region and a fourth end connected to the fourth region, wherein at least a portion of the second frontside conductive layer resistor is situated within a second footprint of the second PIN diode.

9. The device of claim 8, wherein the first region is a P+ region, the second region is an N+ region connected to a VDD backside power contact, the third region is a N+ region and the fourth region is a P+ region connected to a VSS backside power contact.

10. The device of claim 1, comprising a power clamp connected on one side to a VDD backside power contact and on another side to a VSS backside power contact.

11. An electro-static discharge (ESD) power clamp device, comprising:
a power clamp voltage divider including:
a first frontside conductive layer resistor having a first end connected to a VDD power contact and a second end connected to a voltage divider node; and
a second frontside conductive layer resistor having a third end connected to the voltage divider node and a fourth end connected to a VSS power contact;
a first ESD detection circuit connected to the VDD power contact and the voltage divider node;
a first active trigger circuit connected to the first ESD detection circuit and to the VDD power contact and the voltage divider node; and
a field effect transistor circuit connected to the first active trigger circuit and connected on a first side to the VDD power contact and on a second side to the VSS power contact,
wherein the power clamp voltage divider is a thermal sensor having one of a sense or stress pin at the VDD power contact and another one of the sense or stress pin at the VSS power contact.

12. The device of claim 11, comprising:
a second ESD detection circuit connected to the voltage divider node and the VSS power contact;
a second active trigger circuit connected to the second ESD detection circuit and to the voltage divider node and the VSS power contact,
wherein the field effect transistor circuit is connected to the second active trigger circuit.

13. The device of claim 11, wherein the first ESD detection circuit includes a resistor and a capacitor, the resistor having one end connected to the VDD power contact and another end connected to one end of the capacitor and the first active trigger circuit, another end of the capacitor connected to the voltage divider node.

14. The device of claim 11, wherein the first active trigger circuit includes a PMOS transistor in series with an NMOS transistor and connected between the VDD power contact and the voltage divider node.

15. The device of claim 11, wherein the field effect transistor circuit includes a metal-oxide semiconductor field-effect transistor having a first drain/source region connected to the VDD power contact through a first backside via and a second drain/source region connected to the VSS power contact through a second backside via.

16. A method of manufacturing a device, comprising:
forming a PIN diode matrix in a substrate, which includes forming a PIN diode by:
forming a first doped region of the PIN diode;
forming an intrinsic semiconductor region of the PIN diode next to the first doped region; and
forming a second doped region of the PIN diode next to the intrinsic semiconductor region of the PIN diode;
forming a frontside conductive layer resistor having a first end connected to the first doped region and a second end connected to the second doped region,
wherein the PIN diode matrix includes the PIN diode and the frontside conductive layer resistor, such that at least a portion of the frontside conductive layer resistor is situated within a footprint of the PIN diode matrix;
forming a first backside via connected to the first doped region and to a backside pad contact; and
forming a second backside via connected to the second doped region and to a backside power contact.

17. The method of claim 16, comprising:
forming a first connection of frontside conductive layers from the first doped region to the first end of the frontside conductive layer resistor; and
forming a second connection of the frontside conductive layers from the second doped region to the second end of the frontside conductive layer resistor.

18. The method of claim 16, wherein:
forming the first doped region includes forming a P+ region; and
forming the second doped region includes forming an N+ region connected to a VDD backside power contact.

19. The method of claim 16, wherein:
forming the first doped region includes forming an N+ region; and
forming the second doped region includes forming a P+ region connected to a VSS backside power contact.

20. The method of claim 16, comprising:
forming a sense pin of frontside conductive layers connected to the first end of the frontside conductive layer resistor; and
forming a stress pin of the frontside conductive layers connected to the second end of the frontside conductive layer resistor, wherein the frontside conductive layer resistor includes a resistance that is measured by applying a voltage or current to the stress pin and measuring the resistance through the sense pin to measure a temperature.
